(19) United States
(12) Patent Application Publication
(10) Pub. No.: US 2024/0046926 A1
(43) Pub. Date: Feb. 8, 2024

(54) TELEVISION

(71) Applicant: REALTEK SEMICONDUCTOR CORP., Hsinchu (TW)

(72) Inventor: Yen-Hsun Chu, Hsinchu (TW)

(73) Assignee: REALTEK SEMICONDUCTOR CORP., Hsinchu (TW)

(21) Appl. No.: 17/972,061

(22) Filed: Oct. 24, 2022

(30) Foreign Application Priority Data
Aug. 4, 2022 (TW) 111129426

(51) Int. Cl. G10L 15/22; H04R 3/00

(52) U.S. Cl. CPC G10L 15/22; H04R 3/00; G10L 2015/223; H04R 2430/01; H04R 2499/15

(57) ABSTRACT

A television includes a remote control, a receiving element, a speaker, a speech analysis model, and a processor. The processor analyzes video sound to get a repeated audio section after receiving a volume adjustment command from the remote control. Then, the speaker outputs the repeated audio. So that, according to user needs, the television adjusts the video sound before outputting.

### CROSS-REFERENCE TO RELATED APPLICATION

This non-provisional application claims priority under 35 U.S.C. § 119(a) to Patent Application No. 111129426 filed in Taiwan, R.O.C. on Aug. 4, 2022, the entire contents of which are hereby incorporated by reference.

### BACKGROUND

### Technical Field

The disclosure relates to a television, and in particular to a television capable of independently adjusting target volume and a volume control system.

### Related Art

In today's society, televisions have become the center of family entertainment. People can watch television programs, see a film and listen to symphony music on television. All are radiated from the television which is the center. In order to improve user experience, audio enjoyment is also of great significance.

However, when the volume of the existing television is adjusted, all sounds in the video sound needs to be increased or decreased synchronously, and it is impossible to adjust the volume of a single sound. For example, not all people are interested in all sounds played by the television. Sometimes we may just want to concentrate on the voice of the news anchor rather than the background sound when watching the news. Sometimes we may just want to enjoy the music of a symphony concert and mute the broadcaster's commentary.

Therefore, independently adjusting the target volume has become very important to improve the user's enjoyment of television.

### SUMMARY

In view of the problem in the prior art, the inventor provides a television, including: a remote control, a receiving element, a speaker, a speech analysis model and a processor.

The remote control is configured to send a volume adjustment command. The receiving element is configured to receive the volume adjustment command. The speech analysis model is configured to obtain an analyzed audio and hidden layer state information according to a parameter and a video sound. The processor is configured to perform a plurality of operations on the video sound by using the speech analysis model and correspondingly obtain a plurality of the analyzed audios and the hidden layer state information; adjust the volume of the analyzed audios according to the volume adjustment command; obtain a repeated audio section according to the analyzed audios; and control the speaker to output the repeated audio section.

According to the disclosure, in each operation process, the hidden layer state information of the previous operation is retained, and then the operation is performed in conjunction with the repeated audio section, so that the television of the disclosure can process the video sound in real time so as to meet the audio enjoyment and needs of the user.

### BRIEF DESCRIPTION OF THE DRAWINGS

FIG. 1 is a block diagram showing connection of elements according to some examples of the disclosure;

FIG. 2 is a schematic diagram showing operations according to some examples of the disclosure;

FIG. 3 is a schematic diagram showing obtainment of analyzed audios according to some examples of the disclosure;

FIG. 4 is a schematic diagram showing obtainment of analyzed audios according to some examples of the disclosure;

FIG. 5 is a schematic diagram showing obtainment of analyzed audios according to some examples of the disclosure;

FIG. 6 is a schematic diagram showing a remote control according to some examples of the disclosure;

FIG. 7 is a schematic diagram showing a work flow according to some examples of the disclosure; and

FIG. 8 is a schematic working diagram of a speech analysis model according to some examples of the disclosure.

### DETAILED DESCRIPTION

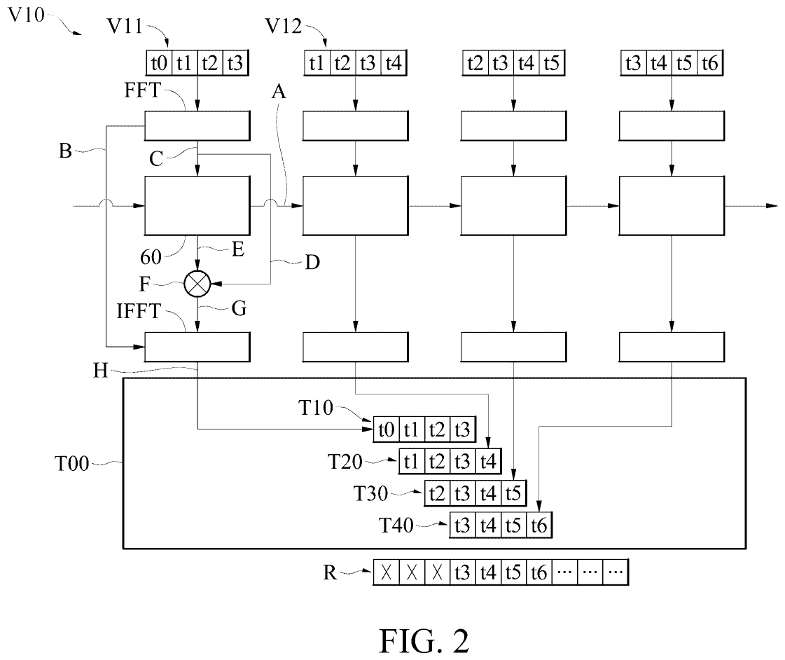

Referring to FIG. 2, FIG. 2 is a schematic diagram showing operations according to some examples of the disclosure. It should be stated first that in FIG. 2, arrow A indicates transmission of the hidden layer state information, arrow B indicates transmission of the phase information, arrows C and D indicate transmission of the magnitude information, arrow E indicates transmission of the mask information, arrow F indicates that the mask information performs masking on the magnitude information, arrow G indicates transmission of the magnitude information subjected to masking, and arrow H indicates transmission of the analyzed audios.

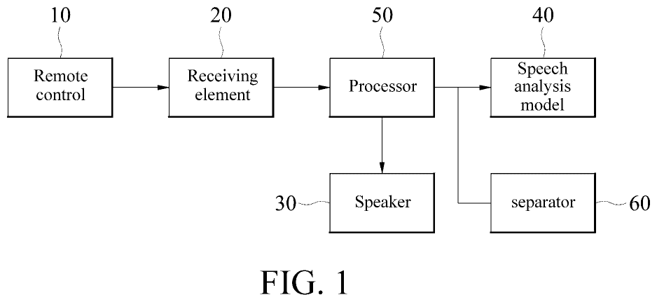

Referring to FIG. 1, a television of the disclosure includes a remote control 10, a receiving element 20, a speaker 30, a speech analysis model 40, a processor 50 and a separator 60. The receiving element 20 is configured to receive a volume adjustment command, and may be, for example, a Bluetooth receiver, an infrared receiver, a network, etc. Any element that can be used to receive the volume adjustment command is the receiving element 20 referred to in this specification. In some examples, the receiving element 20 is an infrared receiver, and the speaker 30 is configured to output sounds.

Referring to FIG. 1, the remote control 10 is configured to send a volume adjustment command. The volume adjustment command may include an overall volume adjustment command and a target volume adjustment command. The overall volume adjustment command is a command for adjusting the volume of human voice and non-human voice in the video sound at the same time with the same adjustment degree. The target volume adjustment command is a command for adjusting the volume of one type of audios in the video sound, for example, human voice, musical instrument sound, ambient sound, etc. This specification is described by taking the target volume adjustment command being used for adjusting the volume of the human voice as an example. The remote control 10 mainly has a plurality of operation buttons that are used to send a command when being pressed. In some examples, the remote control 10 may be a smart phone that sends the volume adjustment command by the aid of a mobile application (app).

Referring to FIG. 1, the speech analysis model 40 is configured to obtain an analysis result and hidden layer state information according to the video sound. In some examples, the analysis result is mask information.

In the analysis process, firstly, magnitude information and phase information are obtained according to the video sound. Referring to FIG. 2, in some examples, the magnitude information and the phase information are obtained by performing a transform on the video sound. The transform may be Fourier transform, fast Fourier transform or short-time Fourier transform (windowed Fourier transform or time dependent-Fourier transform). Taking the short-time Fourier transform as an example, during the transform, the sampling rate of the video sound is 48 kHz, the window length is 4096 sampling points, and the shifting length is 1024 sampling points. Therefore, the time of the window length is about 85.33 ms (4096/48000 millisecond), and the time of the shifting length is about 21.33 ms (1024/48000). Therefore, in the analysis process, the video sound of 85.33 ms is analyzed, and the video sound of 21.33 ms is updated each time. This makes the speech analysis model trained by the method of the disclosure have a higher processing speed and a lower latency and also give consideration to the definition of the audio in the analysis process. The sampling rate of the video sound may be 44.1 kHz, 48 kHz, 96 kHz or 192 kHz. The window length may be 512, 1024, 2048 or 4096 sampling points. In the foregoing example, the window length is 4 times the shifting length, then the shifting length is 128, 256, 512 or 1024 sampling points. In addition, the relationship between the window length and the shifting length is not limited thereto, and the window length may be multiple times the shifting length, such as 2 times, 8 times, 16 times, etc.

After the Fourier transform, the video sound is transformed from the time domain to the frequency domain. Thereby, the phase information may present the relationship between the phase and the frequency in the video sound in the form of a spectrum, where the horizontal axis is frequency, and the vertical axis is phase. Similarly, the magnitude information presents the relationship between the amplitude and the frequency in the video sound in the form of a spectrum, where the horizontal axis is frequency, and the vertical axis is amplitude. After the magnitude information and the phase information are obtained, the speech analysis model 40 analyzes the magnitude information to obtain mask information, the separator 60 performs masking on the magnitude information by using the mask information to obtain a target magnitude information, and then inverse Fourier transform (IFFT) is performed according to the target magnitude information and the phase information to obtain an analyzed audio TOO and hidden layer state information.

In some examples, the mask information is used to mask part of the audio in the magnitude information to retain the rest of the audio. For example, when the human voice audio is to be obtained, the mask information may mask information of musical sound, ambient sound, noise and other sounds in the magnitude information to retain the magnitude information of the human voice. In this way, after the magnitude information of the human voice and the phase information are subjected to inverse Fourier transform, the audio only containing the human voice can be obtained. The obtainment of the musical sound, the ambient sound or other sounds is the same case as the obtainment of the human voice, and details will not be repeated.

Referring to FIG. 1 and FIG. 2, the processor 50 performs a plurality of operations on the video sound by using the speech analysis model 40 and the separator 60 and correspondingly obtains a plurality of analyzed audios TOO and the hidden layer state information; adjust the volume of the analyzed audios TOO according to the volume adjustment command; then obtain a repeated audio section R according to the analyzed audios TOO; and finally control the speaker to output the repeated audio section R. In the operations, during each analysis process using the speech analysis model 40, the hidden layer state information of the previous analysis is used as input information for the next analysis, so that the contents of the previous analysis may be referred to in the analysis process. In some examples, the operation may be a recurrent neural network (RNN) or a long short-term memory (LSTM).

In this way, according to the disclosure, the video sound can be processed in real time and adjusted according to the volume adjustment command, so that the user can control the video sound output by the television according to his own needs.

Referring to FIG. 2, in some examples, before the processor 50 performs operations on a video sound by using the speech analysis model 40, the processor 50 divides the video sound into a plurality of continuous original sub-audio groups V10 at time intervals. Each original sub-audio group V10 includes a plurality of sub-audios (t0, t1, t2, t3, . . . , tn). Taking FIG. 2 as an example, the first original sub-audio group V11 includes a plurality of continuous sub-audios (t0, t1, t2, t3), and the second original sub-audio group V12 includes a plurality of continuous sub-audios (t1, t2, t3, t4), such that the tail signal in the original sub-audio group V10 is the same as the head signal in the next original sub-audio group V10. As can be seen from above, during each analysis process of the original sub-audio group, one part of the sub-audios in the previous original sub-audio group are retained, the other part of the sub-audios are removed and replaced with the same number of other sub-audios, which is helpful to the efficiency of subsequent speech analysis. In addition, the number of the sub-audios removed each time is not limited to the above, and may be two or three, or may be adjusted and changed according to the number of the original sub-audio groups. This example is described by taking one sub-audio removed each time as an example. In some examples, the data volume of the sub-audio is 1024 sampling points at a sampling frequency of 48 KHz (21.33 ms).

In the first operation, the processor 50 performs the operation on the first original sub-audio group V11 by using the speech analysis model 40 and the separator 60. The operation manner is as described above and will not be repeated here. After the operation, a first analyzed audio T10 and hidden layer state information are obtained. Next, in the second operation, the processor 50 uses the hidden layer state information obtained by the first operation and the second original sub-audio group V12 as the input, and performs analysis by using the speech analysis model 40 to obtain a second analyzed audio T20. The operation is repeated in this way to obtain a third analyzed audio T30, a fourth analyzed audio T40, . . . , and then, the overlapping part of the analyzed audios T10-T40 is extracted and output as the repeated audio section R. As shown in the figure, after 4 times of analysis, the overlapping part is the sub-audio t3, so the sub-audio t3 is output as the repeated audio section. In some examples, the repeated audio section R is extracted by an overlap-add method. FIG. 2 is a schematic diagram showing operations according to the disclosure. The working principle of the part not mentioned in the figure is the same as above, and will not be repeated here.

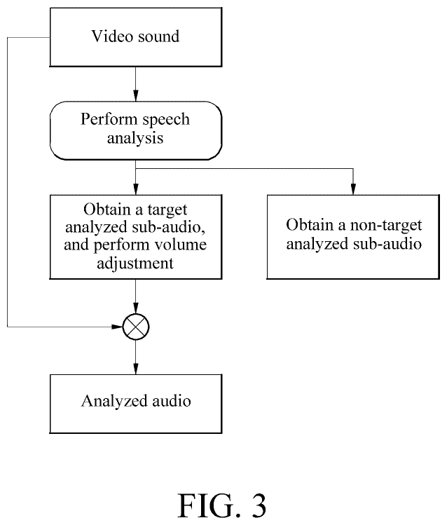

Referring to FIG. 2, in some examples, before the analyzed audio TOO is obtained, the target magnitude information is firstly obtained by the separator 60 according to the mask information and the magnitude information, and then, inverse Fourier transform (IFFT) is performed according to the target magnitude information and the phase information to obtain the target analyzed sub-audio. As shown in FIG. 3, each target analyzed sub-audio is subjected to volume adjustment according to the volume adjustment command and then mixed to the video sound to obtain the analyzed audio TOO. For example, when the user wants to increase the volume of the human voice in the video sound, a human voice audio is obtained as a target analyzed sub-audio by using the speech analysis model 40 and the separator 60. Next, the human voice audio and the video sound are mixed and then output by the speaker 30. At this time, the user may hear the video sound with only the volume of the human voice increased. Alternatively, the human voice audio is kept unchanged, the volume of the video sound is decreased, and then the human voice audio and the video sound are mixed, so that the same effect can be achieved. In this manner, the mixed video sound sounds more saturated and natural.

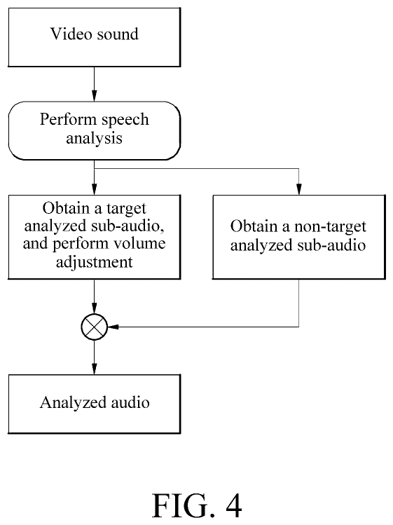

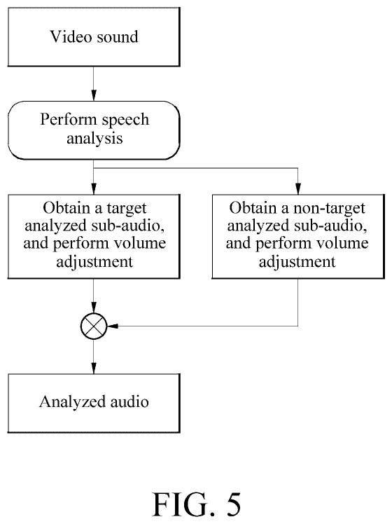

Referring to FIG. 4, in some examples, the speech analysis model 40 and the separator 60 obtain not only the target magnitude information, but also the non-target magnitude information together. Next, in conjunction with the phase information, inverse Fourier transform (IFFT) is performed to obtain the target analyzed sub-audio and the non-target analyzed sub-audio. Taking FIG. 4 as an example, the video sound is analyzed to obtain the target analyzed sub-audio and the non-target analyzed sub-audio. The volume of the non-target analyzed sub-audio is kept unchanged, only the volume of the target analyzed sub-audio is adjusted, and then, the target analyzed sub-audio and the non-target analyzed sub-audio are mixed to obtain the analyzed audio TOO, so that the volume of the target audio in the analyzed audio TOO is highlighted. For example, when the human voice in a song is to be highlighted, the musical instrument volume is kept unchanged, and only the volume of the human voice is adjusted. FIG. 5 is different from FIG. 4 in that the volume of the non-target analyzed sub-audio is also adjusted, and then the target analyzed sub-audio and the non-target analyzed sub-audio are mixed to obtain the analyzed audio TOO. In terms of the above example, at this time, the musical instrument volume is decreased, and the volume of the human voice is increased. Thereby, the mixed audio will highlight the human voice. Alternatively, the volume of the human voice is kept unchanged, but the musical instrument volume is decreased to achieve the same effect.

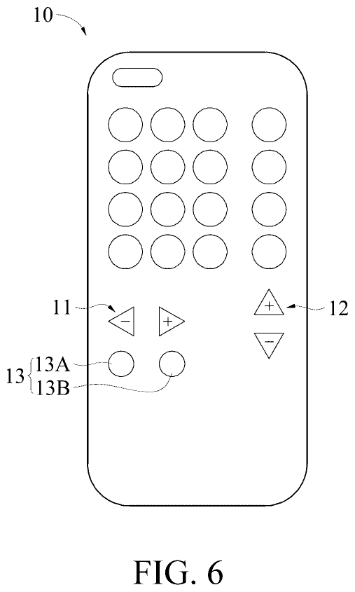

Referring to FIG. 6, in some examples, the volume adjustment command includes a target volume adjustment command. The remote control 10 has a target volume adjustment button 11 for sending the target volume adjustment command. Therefore, the remote control 10 preferably has both an overall volume adjustment button 12 and a target volume adjustment button 11, so that the user can adjust both the overall volume of the video sound and the specific volume in the video sound. Thereby, when the user thinks the television speaker is too loud, he can use the overall volume adjustment button 12. If the user wants to adjust the target audio, he can use the target volume adjustment button 11. In some examples, the user may select the type of the target volume by inputting a command via the remote control 10. For example, when the user inputs a command via the remote control, he may select human voice as the target volume, and may also select musical instrument sound or background sound as the target volume.

In some examples, the volume adjustment command also includes a plurality of mode commands, and the mode commands respectively have different volume adjustment ratios. For example, when one of the mode commands is the KTV mode, it indicates a volume adjustment ratio of human voice being 0 and the musical instrument sound retained, and the above flow is performed according to this mode. Besides, when one of the mode commands is the standard mode, it indicates that the television outputs the original video sound. Thereby, with these mode commands, the user can quickly adjust the audio according to needs. Referring to FIG. 6 again, in accordance with the above example, in some examples, the remote control 10 further has a plurality of mode buttons 13 corresponding to these mode commands, so that the user can quickly control the volume. As described above, the mode buttons 13 include a KTV mode button 13A and a standard mode button 13B that are used to output the corresponding mode command after being pressed, so that the user can quickly switch between various modes.

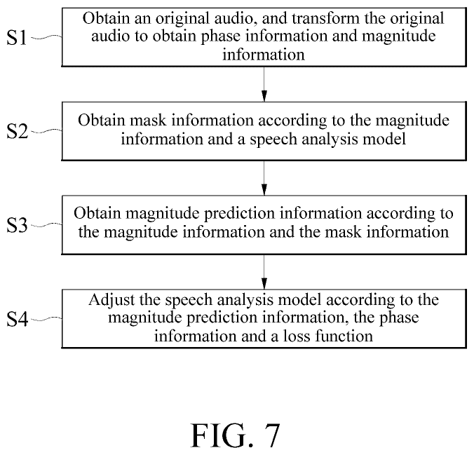

Referring to FIG. 7, in order to make the contents of the disclosure more clearly understood by those of ordinary skill in the art, a training method of the above speech analysis model will be described below. The method includes the following steps:

Step S1: An original audio is obtained and transformed to obtain a phase information and a magnitude information. The original audio may be obtained by recording sound from an environment, a concert or the like by a sound recording element, or by capturing an audio in audio-visual information, or by mixing different types of audios. For example, a musical instrument audio, human voice and ambient sound may be mixed to obtain the original audio. For the implementation of obtaining the original audio by mixing, reference can be made to the description below. The sampling rate of the original audio may be 44.1 kHz, 48 kHz, 96 kHz or 192 kHz.

In step S1, a transform is performed on the original audio. The transform may be Fourier transform, fast Fourier transform or short-time Fourier transform (windowed Fourier transform or time dependent-Fourier transform). Taking the short-time Fourier transform as an example, during the transform, the sampling rate of the original audio is 48 kHz, the window length is 4096 sampling points, and the shifting length is 1024 sampling points. Therefore, the time of the window length is about 85.33 ms (4096/48000), and the time of the shifting length is 21.33 ms (1024/48000). This makes the speech analysis model trained by the method of the disclosure have a higher processing speed and a lower latency and also give consideration to the definition of the audio when being applied to speech recognition. The window length may be 512, 1024, 2048 or 4096 sampling points. In the foregoing example, the window length is 4 times the shifting length, then the shifting length is 128, 256, 512, or 1024 sampling points. In addition, the relationship between the window length and the shifting length is not limited thereto, and the window length may be multiple times the shifting length, such as 2 times, 8 times, 16 times, etc.

In some examples, after the Fourier transform, the original audio is transformed from the time domain to the frequency domain. Thereby, the phase information may present the relationship between the phase and the frequency in the original audio in the form of a spectrum, where the horizontal axis is frequency, and the vertical axis is phase. Similarly, the magnitude information presents the relationship between the amplitude and the frequency in the original audio in the form of a spectrum, where the horizontal axis is frequency, and the vertical axis is amplitude.

Step S2: Mask information is obtained according to the magnitude information and a speech analysis model. The mask information is used to mask part of information in the magnitude information to retain the rest of the magnitude information. For example, when the magnitude information has human voice information and musical instrument sound information, the musical instrument sound information may be selectively masked through the mask information, and the magnitude information with the human voice information is retained. In some examples, non-target mask sub-information is obtained according to the magnitude information and the speech analysis model. In some examples, target mask sub-information and non-target mask sub-information are obtained according to the magnitude information and the speech analysis model.

Step S3: Magnitude prediction information is obtained according to the magnitude information and the mask information. The magnitude information has target magnitude sub-information and non-target magnitude sub-information. Therefore, when the target mask sub-information is used to perform masking on the magnitude information, the target magnitude sub-information will be masked to obtain the non-target magnitude prediction sub-information. Similarly, the non-target mask sub-information will mask the non-target magnitude sub-information in the magnitude information to obtain the target magnitude prediction sub-information.

Step S4: The speech analysis model is adjusted according to the magnitude prediction information, the phase information and a loss function. In some examples, step S4 is to adjust parameters in the speech analysis model. For the examples of this part, reference can be made to the description below. In some examples, the parameters refer to weights that have been trained in the speech analysis model. The loss function, also known as the cost function, is used to evaluate the analysis accuracy of the speech analysis model. Therefore, a smaller value of the loss function indicates a higher accuracy of the speech analysis model. Contrarily, a larger value of the loss function indicates a lower accuracy of the speech analysis model, and the parameters need to be adjusted. For the examples of the loss function, reference can be made to the description below.

In this way, the speech analysis model 40 may be trained by the steps above, so that the mask information obtained by the analysis of the speech analysis model can be effectively used to mask the information in the magnitude information, and thereby, extraction can be performed on the magnitude information by a separator 60. For example, when the original audio has human voice and musical instrument sound, the target mask sub-information may be set to mask the human voice, and the non-target mask sub-information may be set to mask the musical instrument sound. Accordingly, after the separator 60 performs masking on the magnitude information by using the target mask sub-information, the magnitude information with the musical instrument sound can be extracted to serve as the non-target magnitude sub-information. Then, when the magnitude information with the musical instrument sound and the phase information are subjected to inverse Fourier transform, an audio only with the musical instrument sound can be obtained. Similarly, after the separator 60 performs masking on the magnitude information by using the non-target mask sub-information, the magnitude information with the human voice can be extracted to serve as the target magnitude sub-information. Then, when the magnitude information with the human voice and the phase information are subjected to inverse Fourier transform, an audio only with the human voice can be obtained.

In some examples, in step S1, firstly, an original signal is subjected to offline processing or online processing. Taking the extraction of human voice as an example, the offline processing is to perform data enhancement, which produces more data by mixing more types of sound. For example, the human voice is mixed with music to obtain the original audio. For another example, from three types of sound data (human voice, music and noise), two or more types of voice data (including the human voice) are selected and mixed to obtain the original audio. The online processing is to perform data augmentation, which changes the loudness of the original audio by using a random scale, i.e., data=data*random.uniform(low, high). In some examples, low=0.75, and high=0.9. Data inversion may also be performed, i.e., data=data [::−1]. The scale is applied to measure the original audio. Therefore, different loudnesses may be obtained when different scales are used to measure the same original audio.

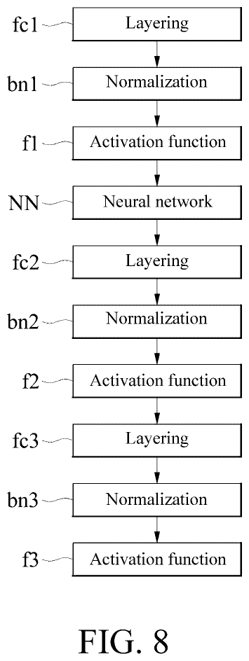

Referring to FIG. 8, in some examples, the speech analysis model firstly performs layering fc1 and normalization bn1 on the original audio, then performs activation function f1, and processes the audio by using a neural network NN. The processed audio is repeatedly subjected to layering fc2, fc3, normalization bn2, bn3, and activation function f2, f3 to obtain the mask information. The normalization reduces the difference between samples, so as to avoid gradient vanishing and gradient explosion in the training process. The normalization may be batch normalization (BN). The activation function mainly allows the speech analysis model to learn a nonlinear relationship from data. The activation function may be step function, sigmoid function, tanh function, relu function or softmax function. The neural network may be recurrent neural networks (RNN) or a long short-term memory (LSTM). In some examples, the layering fc1, fc2, fc3 is to obtain fully connected layers, the normalization bn1, bn2, bn3 is batch normalization, the activation function f1, f2, f3 is a relu function, and the neural network NN is a unidirectional long short-term memory, so that the trained speech analysis model can effectively obtain the mask information.

In some examples, when the mask information obtained in step S2 is the non-target mask sub-information, in step S3, the non-target mask sub-information is used to mask the non-target magnitude sub-information in the magnitude information to obtain the target magnitude prediction sub-information. Taking the obtainment of human voice as an example, the non-target mask sub-information is used to mask music, noise and other information, so that after the magnitude information is subjected to masking by the non-target mask sub-information, the human voice is retained. Next, in step S4, as shown in Formula 1 below, a frequency domain loss sub-function (loss_freq) is obtained according to the target magnitude prediction sub-information (predict_magnitude) and the target magnitude sub-information (target magnitude). MAE is the mean absolute error (MAE).

“loss_freq=MAE(target_magnitude,predict_magnitude)” Formula 1

Then, inverse Fourier transform is performed according to the target magnitude prediction sub-information and the phase information to obtain a target predicted sub-audio (predict_signal). Next, as shown in Formula 2 below, a time domain loss sub-function (loss_time) is obtained according to the original audio (target signal) and the target predicted sub-audio.

“loss_time=MAE(target_signal,predict_signal)” Formula 2

Finally, as shown in Formula 3, the loss function (loss) is obtained according to the time domain loss sub-function and the frequency domain loss sub-function. In some examples, alpha is 0.99.

“loss=alpha*loss_time+(1−alpha)*loss_freq” Formula 3

In some examples, when the mask information obtained in step S2 is the target mask sub-information and the non-target mask sub-information, taking the target being human voice and the non-target being musical sound as an example, in step S3, the target mask sub-information and the non-target mask sub-information are respectively used to perform masking on the magnitude information to obtain the target magnitude prediction sub-information and the non-target magnitude prediction sub-information. Next, in step S4, as shown in Formula 4 below, a frequency domain loss sub-function (l_f) is obtained according to the target magnitude prediction sub-information (p_v_m), the non-target magnitude prediction sub-information (p_m_m), the target magnitude sub-information (t_v_m) and the non-target magnitude sub-information (t_m_m).

“l_f=MAE(t_v_m,p_v_m)+MAE(t_m_m,p_m_m)+MAE(t_v_m+t_m_m,p_v_m+p_m_m)” Formula 4

Then, as shown in Formula 5 below, the original audio includes a target original sub-audio (t_v) and a non-target original sub-audio (t_m), and a time domain loss sub-function (l_t) is obtained according to the target predicted sub-audio (p_v) and the non-target predicted sub-audio (p_m);

“l_t=MAE(t_v,p_v)+MAE(t_m,p_m)+MAE(t_v+t_m,p_v+p_m)” Formula 5

Next, as shown in Formula 6 below, the loss function (loss) is obtained according to the time domain loss sub-function and the frequency domain loss sub-function.

“loss=alpha*l_t+(1−alpha)*l_f” Formula 6

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A television, comprising:
a remote control, configured to send a volume adjustment command;
a receiving element, configured to receive the volume adjustment command;
a speaker;
a speech analysis model, configured to obtain an analysis result and hidden layer state information according to a video sound; and
a processor, configured to:
perform a plurality of operations on the video sound by using the speech analysis model and correspondingly obtain a plurality of analyzed audios and the hidden layer state information;
adjust the volume of the analyzed audios according to the volume adjustment command;
obtain a repeated audio section according to the analyzed audios; and
control the speaker to output the repeated audio section.

2. The television according to claim 1, wherein the processor performs the plurality of operations on the video sound by using the speech analysis model and an separator, obtains a plurality of target analyzed sub-audios and corresponding non-target analyzed sub-audios, performs volume adjustment on each of the target analyzed sub-audios according to the volume adjustment command and mixes the volume-adjusted target analyzed sub-audio with the corresponding non-target analyzed sub-audio to obtain the analyzed audios.

3. The television according to claim 1, wherein the processor performs the plurality of operations on the video sound by using the speech analysis model and an separator, obtains a plurality of target analyzed sub-audios, performs volume adjustment on each of the target analyzed sub-audios according to the volume adjustment command and mixes the volume-adjusted target analyzed sub-audio with the video sound to obtain the analyzed audios.

4. The television according to claim 3, wherein the processor performs the plurality of operations on the video sound by using the speech analysis model to obtain a plurality of pieces of mask information, and the separator obtains the target analyzed sub-audios according to each of pieces of the mask information and the video sound.

5. The television according to claim 4, wherein the operation is performed according to the analyzed audio, the speech analysis model and the hidden layer state information generated by the previous operation.

6. The television according to claim 5, wherein the processor obtains the repeated audio section according to the analyzed audios and an overlap-add method.

7. The television according to claim 6, wherein the volume adjustment command comprises a target volume adjustment command; and the remote control has a target volume adjustment button for sending the target volume adjustment command.

8. The television according to claim 7, wherein the processor divides the video sound into a plurality of continuous original sub-audio groups, each of the original sub-audio groups comprises continuous sub-audios, and a tail sub-audio in the original sub-audio group is the same as a head sub-audio in the next original sub-audio group; and the processor sequentially obtains the original sub-audio groups and performs the plurality of operations by using the speech analysis model.

9. The television according to claim 2, wherein the processor performs the plurality of operations on the video sound by using the speech analysis model to obtain a plurality of pieces of mask information, and the separator obtains the target analyzed sub-audios according to each of pieces of the mask information and the video sound.

10. The television according to claim 9, wherein the operation is performed according to the analyzed audio, the speech analysis model and the hidden layer state information generated by the previous operation.

11. The television according to claim 10, wherein the processor obtains the repeated audio section according to the analyzed audios and an overlap-add method.

12. The television according to claim 11, wherein the volume adjustment command comprises a target volume adjustment command; and the remote control has a target volume adjustment button for sending the target volume adjustment command.

13. The television according to claim 12, wherein the processor divides the video sound into a plurality of continuous original sub-audio groups, each of the original sub-audio groups comprises continuous sub-audios, and a tail sub-audio in the original sub-audio group is the same as a head sub-audio in the next original sub-audio group; and the processor sequentially obtains the original sub-audio groups and performs the plurality of operations by using the speech analysis model.

14. The television according to claim 1, wherein the volume adjustment command comprises a plurality of mode commands, and the mode commands respectively have different volume adjustment ratios.

15. The television according to claim 14, wherein the remote control has a plurality of mode buttons corresponding to the mode commands.
